(19) United States
(12) Patent Application Publication
(10) Pub. No.: US 2025/0201603 A1
(43) Pub. Date: Jun. 19, 2025

(54) METHOD OF TREATING SUBSTRATE

(71) Applicant: SEMES CO., LTD., Cheonan-si (KR)

(72) Inventors: Kwang Hee LEE, Cheonan-si (KR); Hyun Hoo KIM, Cheonan-si (KR); Myung Chan CHO, Asan-si (KR)

(73) Assignee: SEMES CO., LTD., Cheonan-si (KR)

(21) Appl. No.: 18/976,738

(22) Filed: Dec. 11, 2024

(30) Foreign Application Priority Data
Dec. 13, 2023 (KR) 10-2023-0181012

(51) Int. Cl. H01L 21/67; H01L 21/677

(52) U.S. Cl. CPC H01L 21/67253; H01L 21/67781

(57) ABSTRACT

Disclosed is a method of treating a substrate, the method including: seating a first container on a first load port; opening a door of the first container seated on the first load port; after the door of the first container is opened, sequentially taking out one or more sheets of substrates of a first group received in the first container and transferring the taken-out substrates to a substrate treatment unit, and treating the substrates of the first group in the substrate treatment unit; seating a second container on a second load port; opening a door of the second container seated on the second load port; and after the door of the second container is opened, sequentially taking out one or more sheets of the substrates of the second group received in the second container and transferring the taken-out substrates to the substrate treatment unit and treating the substrates of the second group in the substrate treatment unit, in which a timing of opening the door of the second container is determined based on a treatment progress of the substrate of the first group.

### CROSS-REFERENCE TO RELATED APPLICATIONS

This application claims priority to and the benefit of Korean Patent Application No. 10-2023-0181012 filed in the Korean Intellectual Property Office on Dec. 13, 2023, the entire contents of which are incorporated herein by reference.

### TECHNICAL FIELD

The present invention relates to a method of treating a substrate, and more particularly to a method of treating a substrate for determining the time of opening of a container in which a substrate is received.

### BACKGROUND ART

In general, semiconductor devices, such as integrated circuit elements, may be formed by a series of repetitive fine treatment processes on a substrate, such as a silicon wafer. For example, various types of semiconductor devices may be formed on a substrate by repeatedly performing a deposition process to form a thin film on the substrate, an etching process to form the thin film on the substrate into specific patterns, an ion implantation process or diffusion process to impart electrical properties to the patterns, a cleaning and rinsing process to remove impurities from the substrate on which the patterns are formed, and the like.

The foregoing semiconductor manufacturing processes are carried out in high cleanliness process chambers, where the substrates are received in receiving containers, such as Front Open Unified Pods (FOUPs), and transported to a process facility where the semiconductor manufacturing process takes place.

The receiving container has a plurality of slots inside, and the substrate is supported in the slots and received in the receiving container. The substrate in the receiving container is transferred to the process chamber by a substrate transfer device, and the substrate transfer device adjusts the loading position of the substrate based on mapping information generated by a slot mapping device. The slot mapping device detects the substrates in the receiving container and generates mapping information indicating the presence or absence of the substrate for each slot of the receiving container.

On the other hand, when a new substrate transferring device is transferred while a first transferred substrate transferring device is present and a process is being performed on the substrate received in the substrate transferring device, the slot mapping device generates mapping information about the new substrate transferring device regardless of whether the process being performed is terminated or not, and performs the process on the substrate received in the new substrate transferring device as soon as the process being performed is terminated. In this case, there is a problem that the new substrate transferring device may be adversely affected by the process being performed first, and particles may be introduced.

### SUMMARY OF THE INVENTION

The present invention has been made in an effort to provide a method of treating a substrate that is capable of preventing introduction of particles into a new container when a container is replaced.

The present invention has also been made in an effort to provide a method of treating a substrate that minimizes environmental changes caused by an old container to a new container when the container is replaced.

The problem to be solved by the present invention is not limited to the above-mentioned problems, and the problems not mentioned will be clearly understood by those skilled in the art from the descriptions below.

An exemplary embodiment of the present invention provides a method of treating a substrate, the method including: seating a first container on a first load port; opening a door of the first container seated on the first load port; after the door of the first container is opened, sequentially taking out one or more sheets of substrates of a first group received in the first container and transferring the taken-out substrates to a substrate treatment unit, and treating the substrates of the first group in the substrate treatment unit; seating a second container on a second load port; opening a door of the second container seated on the second load port; and after the door of the second container is opened, sequentially taking out one or more sheets of the substrates of the second group received in the second container and transferring the taken-out substrates to the substrate treatment unit and treating the substrates of the second group in the substrate treatment unit, in which a timing of opening the door of the second container is determined based on a treatment progress of the substrate of the first group.

According to the exemplary embodiment, the door of the first container may remain open while the substrate of the first group is unloaded from the first container.

According to the exemplary embodiment, the treatment progress of the substrates of the first group may include the number of substrates of the first group that were not unloaded from the first container.

According to the exemplary embodiment, the treatment process of the substrate of the first group may include an opening or closing state of the door of the first container.

According to the exemplary embodiment, the time of opening the door of the second container may be after the last substrate of the substrates of the first group has been unloaded from the first container.

According to the exemplary embodiment, the time of opening the door of the second container may be the time when the last substrate of the substrates of the first group is unloaded from the first container.

According to the exemplary embodiment, the time of opening the door of the second container may be after the closing of the door of the first container.

According to the exemplary embodiment, before the door of the second container is opened, the type of treatment fluid used for treating the substrates of the first group in the substrate treatment unit may be compared with the type of treatment fluid used for treating the substrates of the second group, and a condition for opening the door of the second container may be differently set based on a result of the comparison.

According to the exemplary embodiment, the opening of the door of the second container may include: opening the door according to a first opening condition when a treatment fluid used for treating the substrate of the first group and a treatment fluid used for treating the substrate of the second group are the same or homogeneous treatment fluids; and opening the door according to a second opening condition when a treatment fluid used for treating the substrate of the first group and a treatment fluid used for treating the substrate of the second group are different treatment fluids, and the first opening condition and the second opening condition may be different.

According to the exemplary embodiment, the first opening condition may be when the last of the substrates of the first group has been unloaded from the first container, and the second opening condition may be after the door of the first container is closed.

According to the exemplary embodiment, when the substrate unloaded from the first container is treated in the substrate treatment unit and an empty third container is seated on a third load port before the door is opened, the door of the third container may be opened simultaneously when the door of the second container is opened, and the third container may be a container into which the substrate of the second group, which have been treated in the substrate treatment unit, is loaded.

According to the exemplary embodiment, when the door of the second container is opened, a mapping process may be performed in the second container before transferring the substrate of the second group to the substrate treatment unit.

Another exemplary embodiment of the present invention provides a method of treating a substrate, the method including: when a first container is seated on an index unit, receiving a first treatment message including first treatment information about a first treatment of the first container; when a second container is seated on the index unit, receiving at least one of a second treatment message including second treatment information about a second treatment of the second container or a message including information about a pair container of the second container; and determining an opening condition of the second container based on at least one of the first treatment information, the second treatment information, or information about the pair container of the second container; and commanding the index unit to open the second container based on the opening condition of the second container.

According to the exemplary embodiment, the determining of the opening condition of the second container may include determining whether the first treatment and the second treatment are the same or homogeneous based on the first treatment information and the second treatment information.

According to the exemplary embodiment, the determining of the opening condition of the second container may include determining, when the first treatment and the second treatment are the same or homogeneous, the opening condition of the second container as a first opening condition, and the first opening condition may be opening the second container at a time when the last substrate of substrates of a first group received in the first container is unloaded from the first container.

According to the exemplary embodiment, the determining of the opening condition of the second container may include determining, when the first treatment and the second treatment are not the same or homogeneous, the opening condition of the second container as a second opening condition, and the second opening condition may be opening the second container at a time when the first treatment is completed on the substrate of the first group received in the first container.

According to the exemplary embodiment, the determining of the opening condition of the second container may include: receiving a message including information about a pair container of a third container when the third container is seated on an index unit; determining, based on the information about the pair container of the second container and the information about the pair container of the third container, whether the second container and the third container are paired; and when the second container and the third container are paired, determining the opening condition of the second container as a third opening condition, and the third opening condition is opening the second container at a time of opening of the third container.

Still another exemplary embodiment of the present invention provides a method of treating a substrate, the method including: seating a first container on a first load port; opening a door of the first container seated on the first load port; after the door of the first container is opened, sequentially taking out one or more sheets of substrates of a first group received in the first container and transferring the taken-out substrates to a substrate treatment unit, and treating the substrates of the first group in the substrate treatment unit; seating a second container on a second load port; opening a door of the second container seated on the second load port; and after the door is opened, sequentially taking out one or more sheets of substrates of a second group received in the second container and transferring the taken-out substrates to the substrate treatment unit and treating the substrates of the second group in the substrate treatment unit, in which the opening of the door of the second container includes: opening the door of the second container according to a first opening condition when a treatment fluid used for treating the substrate of the first group and a treatment fluid used for treating the substrate of the second group are the same or homogeneous treatment fluids; and opening the door of the second container according to a second opening condition when a treatment fluid used for treating the substrate of the first group and a treatment fluid used for treating the substrate of the second group are different treatment fluids, and a timing of opening the door of the second container may be determined based on a treatment progress of the substrate of the first group, the door of the first container may remain open while the substrate of the first group is unloaded from the first container, and the first opening condition may be the time when the last substrate of the substrates of the first group is unloaded from the first container, and the second opening condition may be after the closing of the door of the first container.

According to the exemplary embodiment, the treatment progress of the substrates of the first group may include the number of substrates of the first group that were not unloaded from the first container, or an opening or closing state of the door of the first container.

According to the exemplary embodiment, the time of opening the door of the second container may be after the last substrate of the substrates of the first group has been unloaded from the first container.

According to the exemplary embodiment, when the substrate unloaded from the first container is treated in the substrate treatment unit and an empty third container is loaded onto a third load port before the door is opened, the door of the second container may be opened simultaneously when the door of the second container is opened, and the third container may be a container into which the substrate of the second group, which have been treated in the substrate treatment unit, is loaded.

According to the exemplary embodiment of the present invention, even when a new container is seated during treatment of an existing container, a door of the new container is not opened immediately, thereby preventing particles from entering the new container.

According to the exemplary embodiment of the present invention, even when a new container is seated during treatment of an existing container, a door of the new container is not opened immediately, thereby minimizing environmental changes caused to the new container by the existing container.

According to the exemplary embodiment of the present invention, by simultaneously opening the doors of containers in a paired relationship, the effect of minimizing influences that may occur from other containers may be minimized.

The effect of the present invention is not limited to the foregoing effects, and those skilled in the art may clearly understand non-mentioned effects from the present specification and the accompanying drawings.

### BRIEF DESCRIPTION OF THE DRAWINGS

FIGS. 1 and 2 are top plan views schematically illustrating a substrate treating apparatus according to an exemplary embodiment of the present invention.

FIG. 3 is a perspective view schematically illustrating a container according to the exemplary embodiment of the present invention.

FIG. 4 is a cross-sectional view illustrating an example of a liquid treating chamber according to a first exemplary embodiment of the present invention.

FIG. 5 is a flow diagram of a control method according to the exemplary embodiment of the present invention.

FIG. 6 is a flow diagram of a method of determining an opening condition according to the exemplary embodiment of the present invention.

FIG. 7 is a flow diagram of a method of determining an opening condition according to another exemplary embodiment of the present invention.

FIG. 8 is a flow diagram of a substrate treating method according to an exemplary embodiment of the present invention.

FIG. 9 is a flow diagram of a door opening method according to the exemplary embodiment of the present invention.

FIG. 10 is a conceptual diagram of a substrate treating method according to an exemplary embodiment of the present invention.

FIG. 11 is a conceptual diagram of a substrate treating method according to another exemplary embodiment of the present invention.

FIG. 12 is a conceptual diagram of a substrate treating method according to still another exemplary embodiment of the present invention.

FIG. 13 is a top plan view schematically illustrating a substrate treating apparatus according to another exemplary embodiment of the present invention.

### DETAILED DESCRIPTION

Hereinafter, an exemplary embodiment of the present invention will be described more fully hereinafter with reference to the accompanying drawings, in which exemplary embodiments of the invention are illustrated. However, the present invention may be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “include” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element may be directly coupled to or connected to the other constituent element, but intervening the other constituent elements may also be present. In contrast, when one constituent element is “directly coupled to or “directly connected to” another constituent element, it should be understood that there are no intervening element present. Other expressions describing the relationship between the constituent elements, such as “between ˜ and ˜”, “just between ˜ and ˜”, or “adjacent to ˜” and “directly adjacent to ˜” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

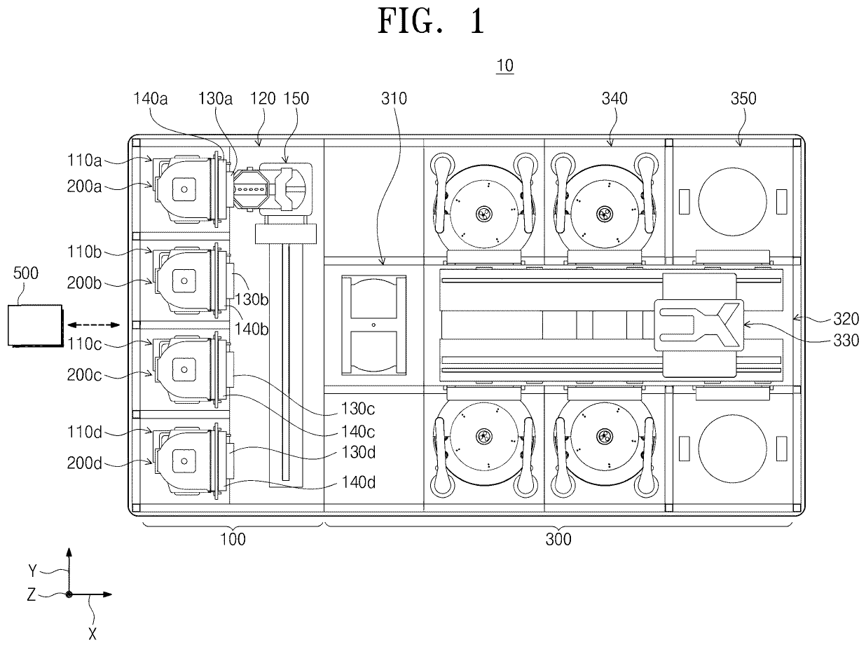

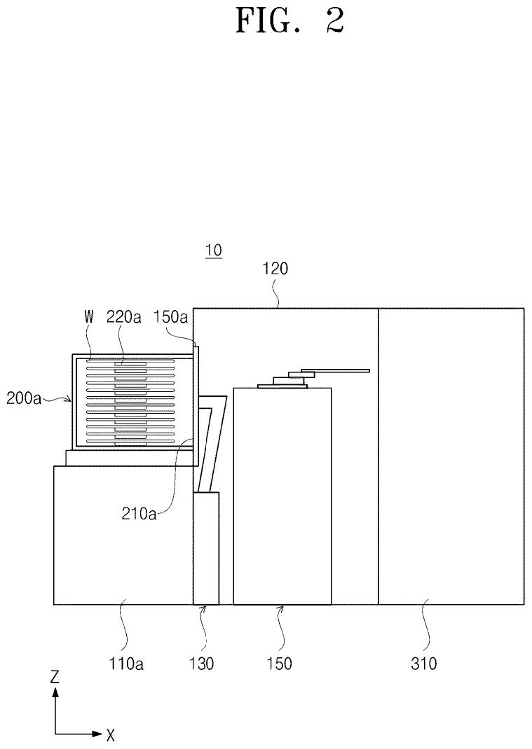

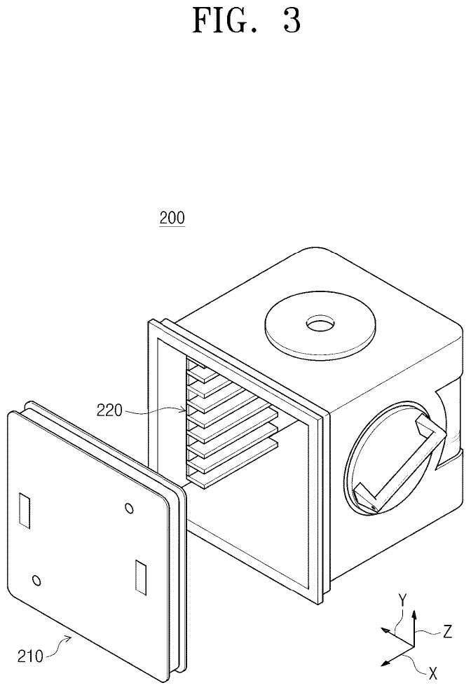

FIGS. 1 and 2 are top plan views schematically illustrating a substrate treating apparatus according to an exemplary embodiment of the present invention. FIG. 3 is a perspective view of a container according to the exemplary embodiment of the present invention.

Referring to FIGS. 1 to 3, a substrate treating apparatus 10 may include an index unit 100, a treatment unit 300, and a control unit 500. When viewed from above, the index unit 100 and the treatment unit 300 are disposed in one direction. Hereinafter, a direction in which the index module 100 and the treatment module 300 are arranged is referred to as a first direction X, and when viewed from above, a direction perpendicular to the first direction X is referred to as a second direction Y, and a direction perpendicular to both the first direction X and the second direction Y is referred to as a third direction Z.

The index unit 100 may transfer a substrate W from a plurality of containers 200 in which the substrate W is received to the treatment unit 300, and may receive the substrate W that has been completely treated in the treatment unit 300 into the plurality of containers 200. A longitudinal direction of the index module 100 is provided in the second direction Y.

The index unit 100 may include a plurality of load ports 110, an index frame 120, a door opener 130, a mapping unit 140, and a first transfer robot 150.

The plurality of load ports 110 may be loaded with a plurality of containers 200. The plurality of containers 200 may be FOUPs. The plurality of load ports 110 may include a first load port 110a, a second load port 110b, a third load port 110c, and a fourth load port 110d. The plurality of containers 200 may include a first container 200a, a second container 200c, a third container 200c, and a fourth container 200d. The drawings illustrate four load ports 110a, 110b, 110c, and 110d and four containers 200a, 200b, 200c, and 200d as the plurality of load ports 110 and the plurality of containers 200, respectively, but this is by way of example and the present invention is not limited thereto.

The first container 200a may be seated on the first load port 110a, the second container 200b may be seated on the second load port 110b, the third container 200c may be seated on the third load port 110c, and the fourth container 200d may be received in the fourth load port 110d.

The first container 200a and the second container 200b may receive the substrate W that is transferred to the process treatment unit 300. The substrate W may be a wafer that is treated in the process chamber 370 described later. The first container 200a may receive substrates of a first group W1, and the second container 200b may receive substrates of a second group W.

The third container 200c and the fourth container 200d may receive the substrates W that have been treated in the process treatment unit 300. In the exemplary embodiment, the second container 200b and the third container 200c may be paired with each other. That is, when the substrate W received in the second container 200b is treated in the process treatment unit 300, the treated substrate W may be received in the third container 200c.

The plurality of containers 200 may be transferred by a container transfer device to the plurality of load ports 110 to be loaded into the load ports 110, or may be unloaded from the plurality of load ports 110 and transferred.

The first container 200a may be loaded by the first load port 110a, or may be unloaded from the first load port 110a and transferred. The second container 200b may be loaded by the second load port 110b, or may be unloaded from the second load port 110b and transferred. The third container 200c may be loaded by the third load port 110c, or may be unloaded from the third load port 110c and transferred. The fourth container 200d may be loaded by the fourth load port 110d, or may be unloaded from the fourth load port 110d and transferred.

The container transfer device may be, but is not limited to, an Overhead Transport Apparatus (OHT), and the containers may be transferred by various devices transferring the plurality of containers 200. Additionally, an operator may load the plurality of containers 200 directly into the plurality of load ports 110, or unload the plurality of containers 200 seated on the plurality of load ports 110 from the plurality of load ports 110.

The index frame 120 may be provided between the plurality of load ports 110 and the process treatment unit 300.

A plurality of door openers 130 may be provided inside the index frame 120. The plurality of door openers 130 may include a first door opener 130a, a second door opener 130b, a third door opener 130c, and a fourth door opener 130d. Four door openers 130a, 130b, 130c, and 140d are illustrated in the drawings as the plurality of door openers 130, but this is by way of example and the present invention is not limited thereto.

The plurality of door openers 130 may open doors 210 of the plurality of containers 200. The first door opener 130a may open a door 210a of the first container 200a, the second door opener 130b may open a door 210b of the second container 200b, the door opener 130c may open a door 210c of the third container 200c, and the door opener 130d may open a door 210d of the fourth container 200d.

When the door 210 is opened, the plurality of mapping units 140 may map a slot 220 of the plurality of containers 200 in which the substrate W is seated and the substrate W. Of the plurality of mapping units 140, a first mapping unit 140a may map the first container 200a, a second mapping unit 140b may map the second container 200b, and a third mapping unit 140c may map the third container 200c.

The first transfer robot 150 may be provided inside the index frame 120. The first transfer robot 150 may transfer the substrate W between the plurality of containers 200 seated on the plurality of load ports 110 and the treatment unit 300.

The process treatment unit 300 may include a buffer chamber 310, a transfer chamber 320, a second transfer robot 330, a liquid treating chamber 340, and a drying chamber 350.

The buffer chamber 310 may provide a space for the substrate W being loaded into the treatment unit 300 and the substrate W being unloaded from the treatment unit 300 to temporarily stay. The liquid treating chamber 340 performs a liquid treating process of treating the substrate W with a liquid by supplying a liquid onto the substrate W. The drying chamber 350 performs a drying process of removing the liquid residual on the substrate W. The transfer chamber 320 may transfer the substrate W between the buffer chamber 310, the liquid treatment chamber 340, and the drying chamber 350.

The buffer chamber 310 may include a plurality of buffers 312 in which the substrate W is placed.

The plurality of buffers 312 may be spaced apart from each other along the third direction Z. The plurality of buffers 312 may be substrate holders that support a bottom surface of the substrate W. The plurality of buffers 312 may be provided in the shape of support shelves that support the bottom surface of the substrate W.

The buffer chamber 310 has an open front face and rear face. The front face is a face facing the index unit 100, and the rear face is a face facing the transfer chamber 320. The first transfer robot 150 may access the buffer chamber 310 through the front face, and the second transfer robot 330 may access the buffer chamber 310 through the rear face.

A longitudinal direction of the transfer chamber 320 may be provided in the first direction X. The buffer chamber 310 may be disposed between the index unit 100 and the transfer chamber 320. The liquid treating chamber 340 and the drying chamber 350 may be disposed at a lateral portion of the transfer chamber 320. The liquid treatment chamber 340 and the transfer chamber 320 may be disposed along the second direction Y. The drying chamber 350 and the transfer chamber 320 may be disposed along the second direction Y. The buffer chamber 310 may be positioned at one end of the transfer chamber 320.

The second transfer robot 330 may be provided in the transfer chamber 320. The second transfer robot 330 may transfer the substrate W between the buffer chamber 310 and the liquid treating chamber 340.

In one example, the liquid treatment chambers 340 are disposed on opposite sides of the transfer chamber 320, the drying chambers 350 are disposed on opposite sides of the transfer chamber 320, and the liquid treatment chambers 340 may be disposed closer to the buffer chamber 310 than the drying chambers 350. At one side of the transfer chamber 320, the liquid treating chambers 340 may be provided in an arrangement of A×B (each of A and B is 1 or a natural larger than 1) in the first direction X and the third direction Z. Further, at one side of the transfer chamber 320, the drying chambers 350 may be provided in number of C×D (each of C and D is 1 or a natural number larger than 1) in the first direction X and the third direction Z. Unlike the description above, only the liquid treating chambers 400 may be provided on one side of the transfer chamber 320, and only the drying chambers 500 may be provided on the other side of the transfer chamber 320.

The control unit 500 may control the substrate treating apparatus 10. The control unit 500 may include a process controller formed of a microprocessor (computer) that executes the control of the substrate treating apparatus 10, a user interface formed of a keyboard in which an operator performs a command input operation or the like in order to manage the substrate treating apparatus 10, a display for visualizing and displaying an operation situation of the substrate treating apparatus 10, and the like, and a storage unit storing a control program for executing the process executed in the substrate treating apparatus 10 under the control of the process controller or a program, that is, a treatment recipe, for executing the process in each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

The control unit 500 may perform control on the index unit 100 and the process treatment unit 300.

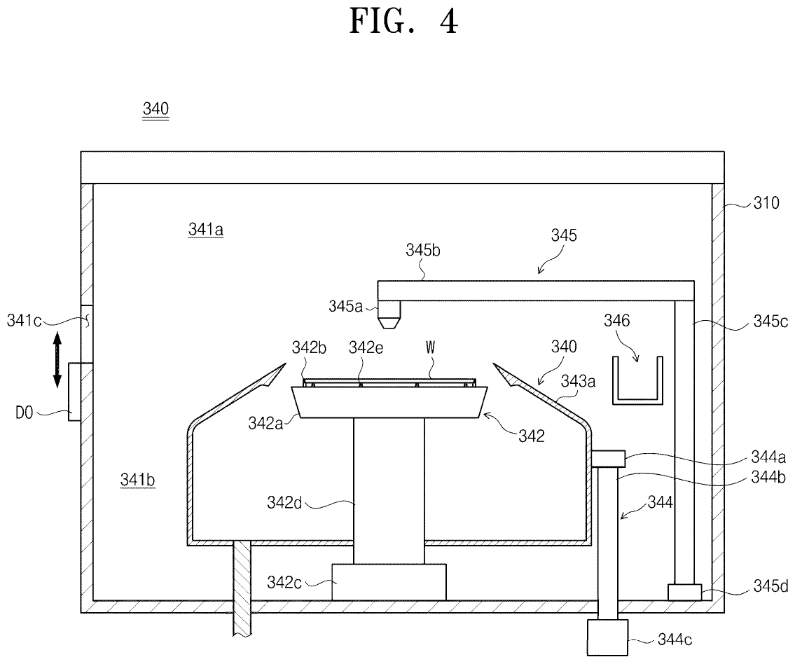

FIG. 4 is a diagram schematically illustrating an example of the liquid treating chamber.

Referring to FIG. 4, the liquid treatment chamber 340 according to the exemplary embodiment of the present invention may treat the substrate W by supplying the substrate W with a treatment liquid. The treatment liquid supplied to the substrate W may be a cleaning solution that cleans the substrate W. The cleaning solution may be deionized water or an organic solvent. The organic solvent may be a solvent containing alcohol. The organic solvent may be isopropyl alcohol (IPA).

The liquid treating chamber 340 may include a housing 341, a support unit 342, a bowl 343, a lifting unit 344, a liquid supply unit 345, and a nozzle waiting cup 346.

The housing 341 may provide a space in which the substrate W is treated, and a space in which some of the configurations of the liquid treating chamber 340 are arranged. The housing 341 may provide an upper space 341a, which is the treatment space where the substrate W is treated, and a lower space 341b, which is located under the upper space 341a.

On one side of the housing 341, an entrance opening 341c may be formed for the substrate W to be loaded into the upper space 341a and for the substrate W to be unloaded from the upper space 341a. The entrance opening 341c may be selectively opened and closed by a door DO, which may be a shutter. The door DO may be configured to be movable in an up and down direction. For example, the door DO may be configured to be moved in an up and down direction by an electric motor, a pneumatic/hydraulic cylinder, or the like.

The support unit 342 may be configured to support and rotate the substrate W in the space provided by the housing 341. The support unit 342 may include a rotation plate 342a, a rotation shaft 342b, and a rotation driver 342c.

The rotation plate 342a may have a substantially circular plate shape when viewed from above. The rotation plate 342a may have the shape of a top surface that is wide and a bottom surface that is narrow. The rotation plate 342a may have a chuck pin 342d and a support pin 342e installed thereon. The chuck pins 342d may be provided in plurality.

The chuck pins 342d may be configured to support the bottom surface and lateral portions of the edge of the substrate W. The chuck pins 342d may be configured to be movable in a direction that is closer to the center of the rotation plate 342a or further away from the center of the rotation plate 342a, when viewed from above. The chuck pin 342d may be configured to be movable in a direction that is closer to the center of the rotation plate 342a or in a direction that is away from the center of the rotation plate 342a by a drive mechanism, such as a motor or cylinder, provided within the rotation plate 342a. When the chuck pin 342d is moved in the direction closer to the center of the rotation plate 342a and is positioned in a chucking position, the substrate W may be chucked onto the rotation plate 342a. Conversely, when the chuck pin 342d is moved in the direction away from the center of the rotation plate 342a and is positioned in a de-chucking position, the substrate W may be de-chucked from the rotation plate 342a.

The support pin 342e may be configured to support the underside of the substrate W. The support pins 342e may be provided in plurality, and may be configured to support different points on the underside of the substrate W, respectively. The support pins 342e may be disposed while being spaced apart from each other along the circumferential direction when viewed from above.

The lower portion of the rotation plate 342a may be coupled with the rotation shaft 342b. The rotation shaft 342b may be rotated clockwise or counterclockwise by receiving drive force from the rotation driver 342c, which may be a hollow motor.

The bowl 343 may provide a space in which the substrate W is treated. The bowl 343 may have a cup shape with an open top. The bowl 343 may function as a liquid receiving part to collect the treatment liquid that is dispersed from the substrate W when the liquid supply unit 345, described later, supplies the treatment liquid to the rotating substrate W.

The bowl 343 may include an outer bowl 343a and an inner bowl 343b. The outer bowl 343a and the inner bowl 343b may include a bottom portion, a lateral portion extending upwardly from the bottom, and a top portion extending inclined from the side portion in a direction approaching the rotation plate 342a. The lateral portion may be coupled with the lifting unit 344 described later. The inner bowl 343b may be a bowl disposed on an inner side of the outer bowl 343a.

A treatment liquid may be collected between the outer bowl 343a and the inner bowl 343b. The collected treatment liquid may be discharged to the outside of the liquid treatment chamber 340 via a line connected to the bottom portion of the outer bowl 343a.

The lifting unit 344 may be configured to change the relative height of the bowl 343 and the rotation plate 342a. The lifting unit 344 may be configured to move the bowl 343 in an up-down direction, thereby changing the relative height of the bowl 343 and the rotation plate 342a. The lifting unit 344 may include a fixing bracket 344a, a lifting shaft 344b, and a lifting driver 344c. The lifting driver 344c, which may be a motor, or a pneumatic/hydraulic cylinder, may move the fixing bracket 344a connected to the lifting shaft 344b in an up-down direction. The fixing bracket 344a is coupled to the lateral portion of the outer bowl 343a, and may move both the outer bowl 343a and the inner bowl 343b in an up-down direction.

The liquid supply unit 345 may supply the substrate W with a treatment liquid. The treatment liquid may be a cleaning solution that cleans the substrate W. The cleaning solution may be deionized water or an organic solvent. The organic solvent may be a solvent containing alcohol. Furthermore, the organic solvent may be isopropyl alcohol (IPA). The liquid supply unit 345 may include a nozzle 345a, a transfer arm 345b, a transfer shaft 345c, and a movement driver 345d. In the exemplary embodiment, the nozzle 345a may mist or dispense the treatment liquid onto the substrate W. The nozzle 345a may be a microdroplet or spray.

The nozzle 345a may be coupled to the transfer arm 345b. Here, the nozzle 345a may be a treatment component, and may be one of round, oval, hollow, or polygonal in cross-section when viewed from below.

The transfer arm 345b may be coupled to the transfer shaft 345c. The transfer shaft 345c may be rotated by the movement driver 345d, which may be a motor. The transfer shaft 345c may be rotatable. Thus, the transfer arm 345b may be pivotable about an axis of rotation of the transfer shaft 345c.

The nozzle 345a may change its position between a process position and a waiting position by rotation of the transfer shaft 345c. The process position may be a position where the nozzle 345a faces the center of the substrate W placed on the rotation plate 342a.

In the example described above, the liquid supply unit 345 is described and illustrated as being provided with a single liquid supply unit, but the liquid supply unit 450 may be provided with a plurality of liquid supply units. Any one of the liquid supply units 345 may be configured to supply deionized water, and another may be configured to supply isopropyl alcohol.

The nozzle waiting cup 346 may provide a waiting space for the nozzle 345a to wait. The nozzle 345a may be positioned in the waiting position, i.e., on top of the nozzle waiting cup 346, when the process is not in progress. The nozzle waiting cup 346 may function as a liquid receiving part to receive a pre-discharged treatment liquid prior to the nozzle 345a starting the process on the substrate W. Additionally, the nozzle waiting cup 346 may function as a liquid receiving part to receive a treatment liquid that is collected at the end of the nozzle 345a while the nozzle 345a is waiting.

A detailed description of the method of performing, by the control unit 500, the control on the index unit 100 and the process treatment unit 300 will be described below.

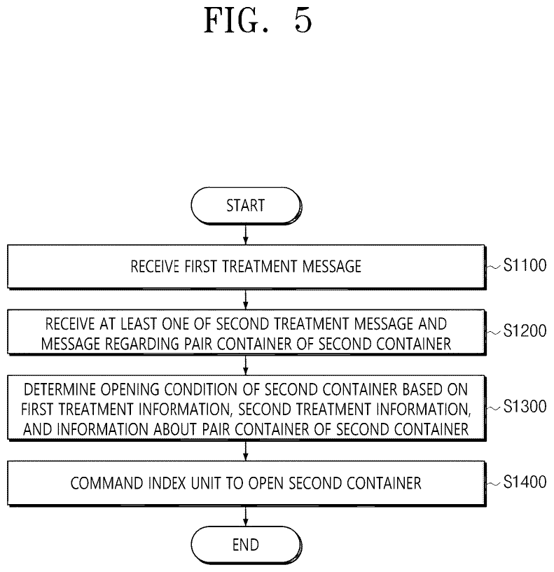

FIG. 5 is a flow diagram of a control method according to an exemplary embodiment of the present invention.

Referring to FIG. 5, the control unit may receive a first treatment message (S1100). When the first container 200a is seated on the index unit 100, the control unit 500 may receive a first treatment message from a server (not illustrated). The first treatment message may include information about a first treatment of the first container 200a. The information about the first treatment may include, when substrates of a first group W received in the first container 200a is treated by the substrate treatment unit 300, the treatment method performed by the substrate treatment unit 300, or the type of fluid used for treating the substrates of the first group W.

The control unit may receive at least one of a second treatment message and a message regarding a pair container of the second container (S1200). When the second container 200b is seated on the index unit 100, the control unit 500 may receive a second treatment message from the server (not illustrated). The second treatment message may include information about a second treatment of the second container 200b. The information about the second treatment may include, when the substrates of the second group W received in the second container 200b is treated by the substrate treatment unit 300, the treatment method performed by the substrate treatment unit 300, or the type of fluid used for treating the substrates of the second group W.

The message about the pair container of the second container may contain information about the pair container of the second container. The pair container of the second container may be a container in which the treated substrates W of the second group is received when the second treatment has been performed on the substrates of the second group W received in the second container.

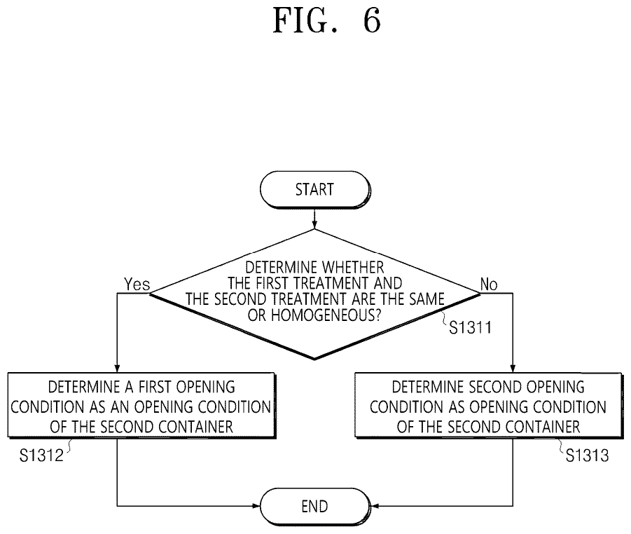

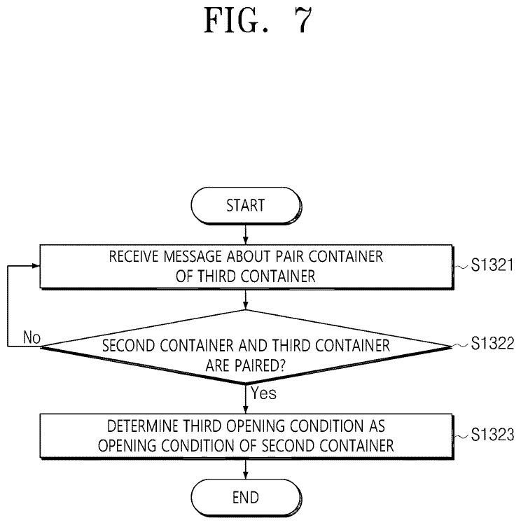

The control unit may determine an opening condition of the second container (S1300). The control unit 500 may determine the opening condition of the second container 100c based on at least one of the first treatment message, the second treatment message, or the message regarding the pair container of the second container. The method of determining, by the control unit 500, the opening condition of the second container 200b may be as illustrated in FIGS. 6 and 7.

FIG. 6 is a flow diagram of the method of determining the opening condition according to the exemplary embodiment of the present invention.

FIG. 6 illustrates the method of determining, by the control unit 500, the opening condition of the second container 200b based on the first treatment message and the second treatment message.

Referring to FIG. 6, the control unit may determine whether the first treatment and the second treatment are the same or homogeneous (S1311). The control unit 500 may determine whether the first treatment and the second treatment are the same or homogeneous based on information about the first treatment included in the first treatment message and information about the second treatment included in the second treatment message. When the method of treating, by the substrate treatment unit 300, the substrates of the first group W and the method of treating, by the substrate treatment unit 300, the substrates of the second group W are the same or homogeneous, the control unit 500 may determine that the first treatment and the second treatment are the same or homogeneous. Alternatively, when the fluid used by the substrate treatment unit 300 to process the substrates W of the first group and the fluid used to process the substrates W of the second group are the same or homogeneous, the control unit 500 may determine that the first treatment and the second treatment are the same or homogeneous.

For example, when the fluid used for treating the substrates W of the first group is CPN or HF or SC1, or the fluid used for treating the substrates W of the first group is CPN, HF, or SC1, or is a fluid that is not influenced by CPN, HF, or SC1, the control unit 500 may determine that the fluid used for treating the substrates W of the first group and the fluid used for treating the substrates W of the second group are the same or homogeneous.

When the first treatment and the second treatment are the same or homogeneous (YES in S1311), the control unit may determine a first opening condition as an opening condition of the second container (S1312). The first opening condition may be to open the second container 200b at a time when the last substrate W of the substrates of the first group received in the first container 200a is unloaded from the first container 200a.

When the first treatment and the second treatment are the same or heterogeneous (NO in S1311), the control unit may determine a second opening condition as an opening condition of the second container (S1313). The second opening condition may be to open the second container at a time when the first treatment is completed on the substrates of the first group received in the first container.

FIG. 7 is a flow diagram of a method of determining an opening condition according to another exemplary embodiment of the present invention.

FIG. 7 illustrates a method of determining, by the control unit 500, an opening condition of the second container 200b based on the message about the pair container of the second container.

Referring to FIG. 7, the control unit may receive a message about a pair container of the third container (S1321). The message about the pair container of the third container may include information about the pair container of the third container 200c.

The control unit may determine that the second container and the third container are paired (S1322). The control unit may determine that the second container 200b and the third container 200c are paired based on the message about the pair container of the second container and the information about the pair container of the third container

When the second container and the third container are paired (YES in S1322), the control unit may determine a third opening condition as an opening condition of the second container (S1323). The third opening condition may be to open the second container at the time of opening of the third container.

Referring again to FIG. 6, the control unit may command the index unit to open the second container (S1400). The control unit 500 may command the index unit 100 to open the second container according to one of the first opening condition, the second opening condition, and the third opening condition determined by the method described above.

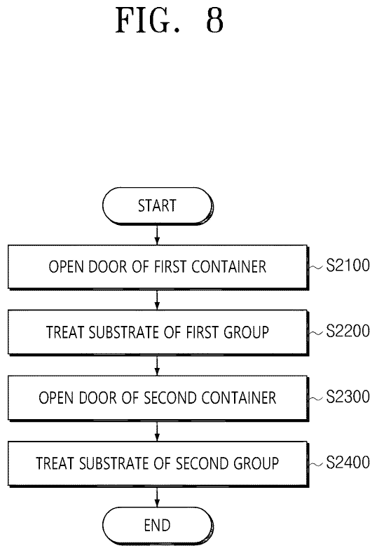

FIG. 8 is a flow diagram of a substrate treating method according to an exemplary embodiment of the present invention.

Referring to FIG. 8, the substrate treating apparatus may open a door of a first container (S2100). The first container 200a may be seated on the substrate treating apparatus 10. The first container 200a may be seated on the first load port 110a. The substrate treating apparatus 10 may open a door 210a of the first container 200a seated on the first load port 110a. The substrate treating apparatus 10 may open the door 210a of the first container 200a via the door opener 130a.

The substrate treating apparatus is capable of treating substrates of a first group (S2200). The substrate treating apparatus 10 may perform mapping in the first container 200a. The substrate treating apparatus 10 may perform mapping in the first container 200a via the first mapping unit 140a.

After the door 210a of the first container 200a is opened, the substrate treating apparatus 10 may sequentially take out one or more sheets of the substrates of the first group W received in the first container 200a and transfer them to the substrate treatment unit 300. The substrate treating apparatus 10 may transfer the substrates W of the first group to the substrate treatment unit 300 via the first transfer robot 150.

In this case, the door 210a of the first container 200 may remain open. The substrate treating apparatus 10 may process the substrates W of the first group. The substrate treating apparatus 10 may process the substrates W of the first group via the substrate treatment unit 300. The substrate treating apparatus 10 may perform a first treatment on the substrates W of the first group.

The substrate treating apparatus may open the door of the second container (S2300). The second container 200b may be seated on the substrate treating apparatus 10. The second container 200b may be seated on the second load port 110b. The substrate treating apparatus 10 may open the door 210b of the second container 200b seated on the second load port 110b. The timing of opening the door 210b of the second container 200b may be determined based on the treatment progress of the substrate W of the first group. This may include the number of substrates W of the first group that have not been unloaded from the first container 210a, or the state of opening or closing of the door of the first container.

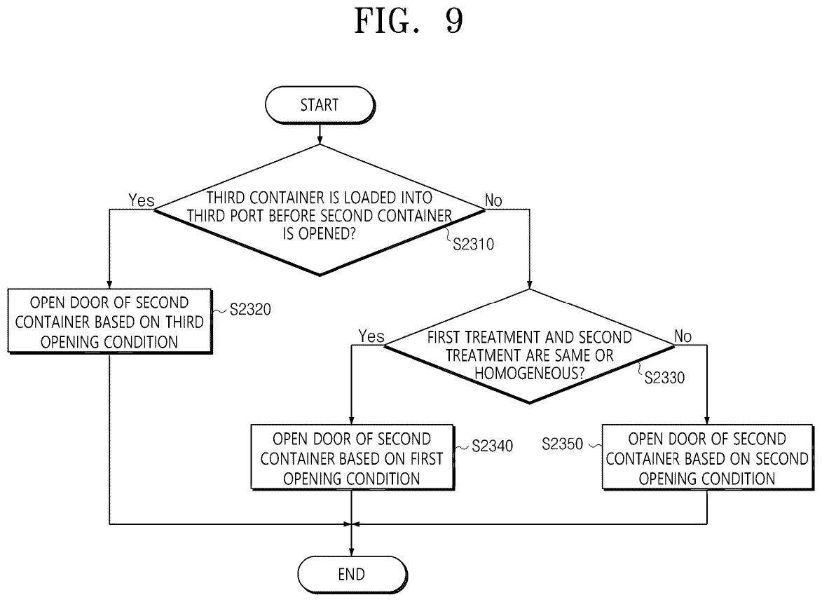

A detailed description of the method of opening, by the substrate treating apparatus 10, the door 210b of the second container 200b may be illustrated in following FIG. 9.

FIG. 9 is a flow diagram illustrating a door opening method according to an exemplary embodiment of the present invention.

Referring to FIG. 9, the substrate treating apparatus may determine that the third container is seated before the second container is opened (S2310). The third container 200c may be seated on the third load port 110c.

When the third container is seated before the second container is opened (YES in S2310), the substrate treating apparatus may open the door 210c of the third container 200c based on a third opening condition (S2320). The third opening condition may be opening the door 210c of the second container 200c at the time of opening the door 210c of the third container 200c. The substrate treating apparatus 10 may open the door 210b of the second container 200b and the door 210c of the third container 200c simultaneously. The substrate treating apparatus 10 may open the door 210b of the second container 200b seated on the second load port 110b and open the door 210c of the third container 200c seated on the third load port 110c. The substrate treating apparatus 10 may open the door 210b of the second container 200b via the door opener 130b, and may open the door 210c of the third container 200c via the door opener 130c.

When the third container is not seated before the second container is opened (NO in S2310), the substrate treating apparatus 10 may determine whether the first treatment and the second treatment are the same or homogeneous (S2330). The second treatment may relate to the method of treating the substrates of the second group W received in the second container 200b. When the method of treating the substrates W of the first group and the method of treating the substrates W of the second group are the same or homogeneous, the substrate treating apparatus 10 may determine that the first treatment and the second treatment are the same or homogeneous. Alternatively, when the fluid used to treat the substrate W of the first group and the fluid used to treat the substrate W of the second group are the same or homogeneous, the substrate treating apparatus 10 may determine that the first treatment and the second treatment are the same or homogeneous.

When the first and second treatments are the same or homogeneous (YES of S2330), the substrate treating apparatus may open the door of the second container based on the first opening condition (52340). The first opening condition may be to open the second container 200b at a time when the last substrate W of the substrates of the first group received in the first container 200a is unloaded from the first container 200a.

The substrate treating apparatus 10 may open the door 210b of the second container 200b at a time when the last of the substrates W of the first group received in the first container 200a is unloaded from the first container 200a. The substrate treating apparatus 10 may open the door 210b of the second container 200b seated on the second load port 110b. The substrate treating apparatus 10 may open the door 210b of the second container 200b via the door opener 130b.

When the first treatment and the second treatment are different (NO of S2330), the substrate treating apparatus may open the door of the second container based on the second opening condition (S2350). The second opening condition may be to open the door 210b of the second container 200b at a time when the first treatment is completed on the substrates of the first group W received in the first container 200a. The substrate treating apparatus 10 may open the door 210b of the second container 200b at a time when the first treatment is completed on the substrates W of the first group.

In the exemplary embodiment, the substrate treating apparatus 10 may open the door 210b of the second container 200b after the door 210a of the first container 200a is closed.

The substrate treating apparatus 10 may open the door 210b of the second container 200b seated on the second load port 110b. The substrate treating apparatus 10 may open the door 210b of the second container 200b via the door opener 130b.

Referring again to FIG. 8, the substrate treatment unit may process the substrates of the second group (S2400). The substrate treating apparatus 10 may perform mapping in the second container 200b. The substrate treating apparatus 10 may perform mapping in the first container 200b via the second mapping unit 140b.

After the door 210b of the second container 200b is opened, the substrate treating apparatus 10 may sequentially take out one or more sheets of the substrates of the second group W received in the second container 200b and transfer them to the substrate treatment unit 300. The substrate treating apparatus 10 may transfer the substrates W of the second group to the substrate treatment unit 300 via the second transfer robot 150. In this case, the door 210b of the second container 200b may remain open.

The substrate treatment unit 10 may treat the substrates of the second group. The substrate treating apparatus 10 may treat the substrates W of the second group via the substrate treatment unit 300. The substrate treating apparatus 10 may perform a second treatment on the substrates W of the second group. When the door 210c of the third container 200c is opened in operation S2320, the substrate treating apparatus 10 may receive the substrate W of the second group on which the second treatment was performed into the door 210c of the third container 200c.

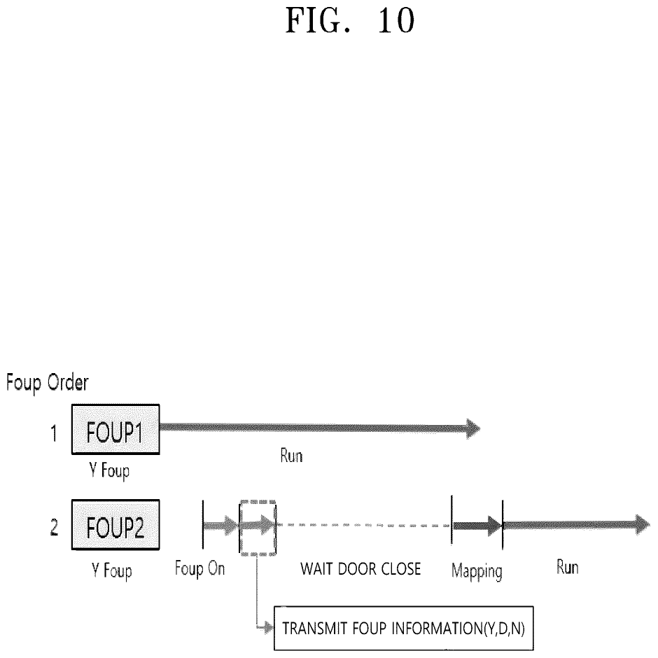

FIG. 10 is a conceptual diagram of the substrate treating method according to the exemplary embodiment of the present invention.

In FIG. 10, FOUP 1 and FOUP 2 may correspond to the first container 200 and the second container 400 described above, and the same or homogeneous treatment may be performed on the substrate included in FOUP 1 and the substrate included in FOUP 2. The substrate included in FOUP 1 and the substrate included in FOUP 2 may be a substrate of the first group and a substrate of the second group, respectively.

Referring to FIG. 10, when treatment (RUN) is performed on the substrate contained in FOUP 1, FOUP 2 may be seated (FOUP ON) in the load port 110. In this case, the server (not illustrated) may communicate FOUP information about a second FOUP to the control unit 500. For example, the FOUP information about the second FOUP may correspond to the second treatment message described above and may be expressed as, but not limited to, Y, D, and N. When FOUP 1 is Y and FOUP 2 is Y or D, the treatments for the substrate included in FOUP 1 and for the substrate included in FOUP 2 may be the same or homogeneous, when FOUP 1 is N and FOUP 2 is N or D, the treatments for the substrate included in FOUP 1 and for the substrate included in FOUP 2 may be the same or homogeneous, when FOUP 1 is Y and FOUP 2 is N, or when FOUP 1 is N and FOUP 2 is Y, the treatments for the substrate included in FOUP 1 and for the substrate included in FOUP 2 may be different.

When the treatment for the substrates included in FOUP 1 and the treatment for the substrates included in FOUP 2 are the same or homogeneous, FOUP 2 may be opened at the time the last of the substrates included in FOUP 1 is unloaded from FOUP 1, and the mapping for the substrate included in FOUP 2 may be performed.

The treatment of the substrate included in FOUP 1 may be completed while mapping of the substrate included in FOUP 2 is being performed, and the treatment of the substrate included in FOUP 2 may be performed when the mapping of the substrate included in FOUP 2 is completed.

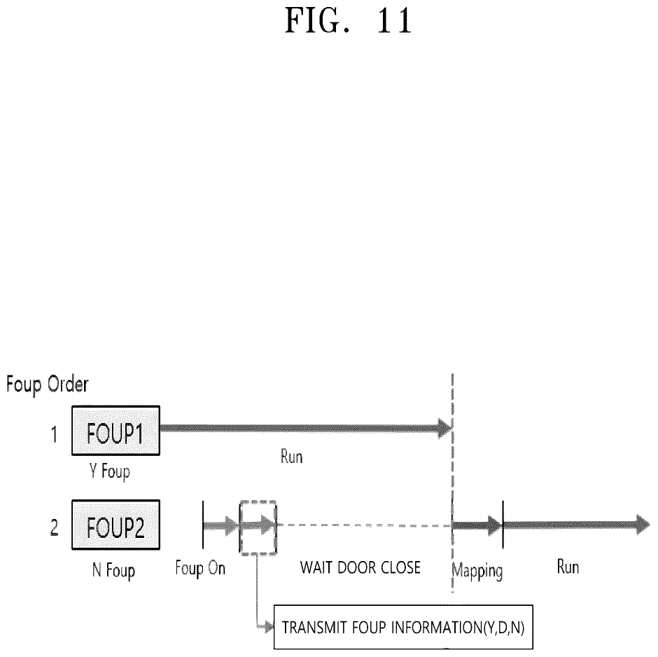

FIG. 11 is a conceptual diagram of a substrate treating method according to another exemplary embodiment of the present invention.

In FIG. 11, FOUP 1 and FOUP 2 may correspond to the first container 200 and the second container 400 described above, and different treatments may be performed on the substrate included in FOUP 1 and the substrate included in FOUP 2. The substrate included in FOUP 1 and the substrate included in FOUP 2 may be a substrate of the first group and a substrate of the second group, respectively.

Referring to FIG. 11, when treatment is performed on the substrate included in FOUP 1, FOUP 2 may be seated on the load port 110. In this case, the server (not illustrated) may communicate FOUP information about a second FOUP to the control unit 500.

When the treatment for the substrate included in FOUP 1 and the treatment for the substrate included in FOUP 2 are different, FOUP 2 may be opened at the time when treatment for the substrate included in FOUP 1 is complete, and mapping to the substrate included in FOUP 2 may be performed. Once the mapping for the substrate included in FOUP 2 is complete, the treatment for the substrate included in FOUP 2 may be performed.

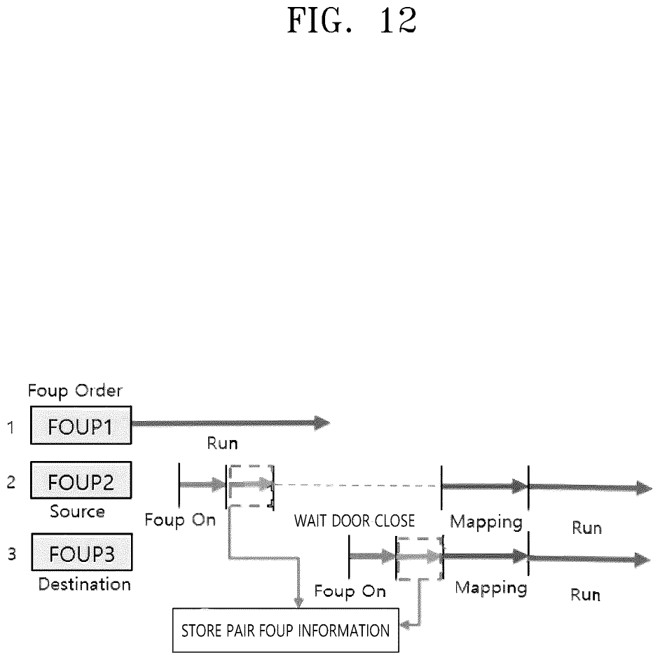

FIG. 12 is a conceptual diagram of a substrate treating method according to still another exemplary embodiment of the present invention.

In FIG. 12, FOUP 1, FOUP 2, and FOUP 3 may correspond to the first container 200, the second container 400, and the third container 600 described above. FOUP 2 and FOUP 3 may be paired with each other as a source and a destination. The substrate included in FOUP 1 and the substrate included in FOUP 2 may be a substrate of the first group and a substrate of the second group, respectively.

Referring to FIG. 12, when treatment is performed on the substrate included in FOUP 1, FOUP 2 may be seated on the load port 110. In this case, the server (not illustrated) may communicate pair FOUP information about the second FOUP to the control unit 500, and the control unit 500 may store the pair FOUP information about the second FOUP. The pair FOUP information about the second FOUP may be a message regarding the pair FOUP of the second container 400 described above.

When treatment of the substrate contained in FOUP 2 is complete, FOUP 3 may be seated on load port 110. The server (not illustrated) may transmit pair FOUP information about the third FOUP to the control unit 500, and the control unit 500 may store the pair FOUP information about the third FOUP. The pair FOUP information about the third FOUP may be a message regarding the paired container of the third container 600 described above.

When the second FOUP and the third FOUP are paired, the second FOUP and the third FOUP may be opened at the same time, a mapping may be performed on the substrate contained in the second FOUP, and a mapping may be performed on the third FOUP. The treatment may be performed on the substrate contained in FOUP 2, and the treated substrate may be transferred to FOUP 3.

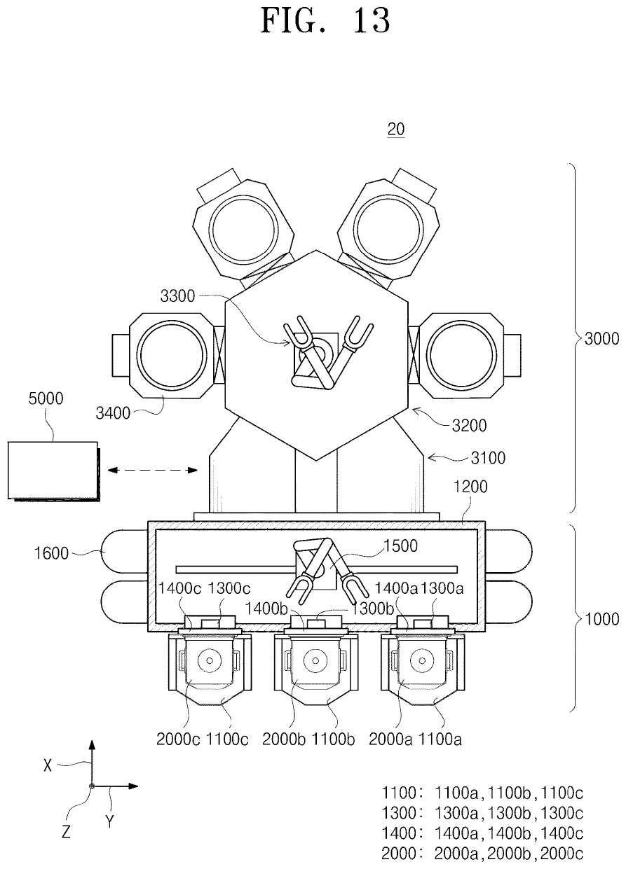

FIG. 13 is a top plan view schematically illustrating a substrate treating apparatus according to another exemplary embodiment of the present invention.

Referring to FIG. 13, a substrate treating apparatus 20 according to another exemplary embodiment of the present invention may include an index unit 1000, a process treatment unit 3000, and a control unit 5000.

The index unit 1000 may include a plurality of load ports 1100, an index frame 1200, a door opener 1300, a mapping unit 1400, a first transfer robot 1500, and a side buffer 1600. The plurality of load ports 1100, the index frame 1200, the door opener 1300, the mapping unit 1400, and the first transfer robot 1500 may be configured the same or similar to the plurality of load ports 110, the index frame 120, the door opener 130, the mapping unit 140, and the first transfer robot 150 described with reference to FIGS. 1 to 3.

The side buffer 1600 may be installed on one side of the index chamber 1200. The side buffer 1600 may be a storage part for storing the substrate W. Additionally, some of the side buffers 1600 may be provided with an alignment unit to align the substrate W.

The process treatment unit 3000 may include a load lock chamber 3100, a transfer chamber 3200, a second transfer robot 3300, and a process chamber 3400. The load lock chamber 3100, the transfer chamber 3200, and the second transfer robot 3300 may be configured the same as or similar to the buffer chamber 310, the transfer chamber 320, and the second transfer robot 330 described with reference to FIGS. 1 to 3.

The process chamber 3400 may be a liquid treatment chamber that treats the substrate by supplying the substrate with a treatment liquid. Additionally, the process chamber 3400 may be a plasma chamber that utilizes plasma to treat the substrate. Further, some of the process chambers 3400 may be liquid treatment chambers that treat the substrate by supplying a treatment liquid to the substrate, and other of the process chambers 3400 may be plasma chambers that treat the substrate by using plasma. However, the present invention is not limited thereto, and the substrate treatment process performed in the process chambers 3400 may be varied to any known substrate treatment process. Further, when the process chamber 3400 is a plasma chamber that utilizes plasma to treat the substrate, the plasma chamber may be a chamber that performs an etching or ashing process to remove a thin film on the substrate by using plasma, but the present invention is not limited thereto. For example, the plasma treatment process performed in the process chamber 3400 may be variously modified to any known plasma treatment process.

The control unit 5000 may be configured the same or similar to the control unit 500 described with reference to FIGS. 1 to 3.

The foregoing detailed description illustrates the present invention. Further, the above content shows and describes the exemplary embodiment of the present invention, and the present invention may be used in various other combinations, modifications, and environments. That is, the foregoing content may be modified or corrected within the scope of the concept of the invention disclosed in the present specification, the scope equivalent to that of the invention, and/or the scope of the skill or knowledge in the art. The foregoing exemplary embodiment describes the best state for implementing the technical spirit of the present invention, and various changes required in specific application fields and uses of the present invention are possible. Accordingly, the detailed description of the invention above is not intended to limit the invention to the disclosed exemplary embodiment. Further, the accompanying claims should be construed to include other exemplary embodiments as well.

What is claimed is:

1. A method of treating a substrate, the method comprising:
seating a first container on a first load port;
opening a door of the first container seated on the first load port;
after the door of the first container is opened, sequentially taking out one or more sheets of substrates of a first group received in the first container and transferring the taken-out substrates to a substrate treatment unit, and treating the substrates of the first group in the substrate treatment unit;
seating a second container on a second load port;
opening a door of the second container seated on the second load port; and
after the door of the second container is opened, sequentially taking out one or more sheets of the substrates of the second group received in the second container and transferring the taken-out substrates to the substrate treatment unit and treating the substrates of the second group in the substrate treatment unit,
wherein a timing of opening the door of the second container is determined based on a treatment progress of the substrate of the first group.

2. The method claim 1, wherein the door of the first container remains open while the substrate of the first group is unloaded from the first container.

3. The method claim 1, wherein the treatment progress of the substrates of the first group includes the number of substrates of the first group that were not unloaded from the first container.

4. The method claim 1, wherein the treatment process of the substrate of the first group includes an opening or closing state of the door of the first container.

5. The method claim 1, wherein the time of opening the door of the second container is after the last substrate of the substrates of the first group has been unloaded from the first container.

6. The method claim 1, wherein the time of opening the door of the second container is the time when the last substrate of the substrates of the first group is unloaded from the first container.

7. The method claim 1, wherein the time of opening the door of the second container is after the closing of the door of the first container.

8. The method claim 1, wherein before the door of the second container is opened, the type of treatment fluid used for treating the substrates of the first group in the substrate treatment unit is compared with the type of treatment fluid used for treating the substrates of the second group, and a condition for opening the door of the second container is differently set based on a result of the comparison.

9. The method claim 1, wherein the opening of the door of the second container includes:
opening the door according to a first opening condition when a treatment fluid used for treating the substrate of the first group and a treatment fluid used for treating the substrate of the second group are the same or homogeneous treatment fluids; and
opening the door according to a second opening condition when a treatment fluid used for treating the substrate of the first group and a treatment fluid used for treating the substrate of the second group are different treatment fluids, and
the first opening condition and the second opening condition are different.

10. The method of claim 9, wherein the first opening condition is when the last of the substrates of the first group has been unloaded from the first container, and
the second opening condition is after the door of the first container is closed.

11. The method claim 1, wherein when the substrate unloaded from the first container is treated in the substrate treatment unit and an empty third container is seated on a third load port before the door is opened, the door of the third container is opened simultaneously when the door of the second container is opened, and
the third container is a container into which the substrate of the second group, which has been treated in the substrate treatment unit, is loaded.

12. The method of claim 11, wherein when the door of the second container is opened, a mapping process is performed in the second container before transferring the substrate of the second group to the substrate treatment unit.

13. A method of treating a substrate, the method comprising:
when a first container is seated on an index unit, receiving a first treatment message including first treatment information about a first treatment of the first container;
when a second container is seated on the index unit, receiving at least one of a second treatment message including second treatment information about a second treatment of the second container or a message including information about a pair container of the second container; and
determining an opening condition of the second container based on at least one of the first treatment information, the second treatment information, or information about the pair container of the second container; and
commanding the index unit to open the second container based on the opening condition of the second container.

14. The method of claim 13, wherein the determining of the opening condition of the second container includes determining whether the first treatment and the second treatment are the same or homogeneous based on the first treatment information and the second treatment information.

15. The method of claim 14, wherein the determining of the opening condition of the second container includes determining, when the first treatment and the second treatment are the same or homogeneous, the opening condition of the second container as a first opening condition, and
the first opening condition is opening the second container at a time when the last substrate of substrates of a first group received in the first container is unloaded from the first container.

16. The method of claim 14, wherein the determining of the opening condition of the second container includes determining, when the first treatment and the second treatment are not the same or homogeneous, the opening condition of the second container as a second opening condition, and
the second opening condition is opening the second container at a time when the first treatment is completed on the substrate of the first group received in the first container.

17. The method of claim 13, wherein the determining of the opening condition of the second container includes:
receiving a message including information about a pair container of a third container when the third container is seated on an index unit;
determining, based on the information about the pair container of the second container and the information about the pair container of the third container, whether the second container and the third container are paired; and
when the second container and the third container are paired, determining the opening condition of the second container as a third opening condition, and
the third opening condition is opening the second container at a time of opening of the third container.

18. A method of treating a substrate, the method comprising:
seating a first container on a first load port;
opening a door of the first container seated on the first load port;
after the door of the first container is opened, sequentially taking out one or more sheets of substrates of a first group received in the first container and transferring the taken-out substrates to a substrate treatment unit, and treating the substrates of the first group in the substrate treatment unit;
seating a second container on a second load port;
opening a door of the second container seated on the second load port; and
after the door is opened, sequentially taking out one or more sheets of substrates of a second group received in the second container and transferring the taken-out substrates to the substrate treatment unit and treating the substrates of the second group in the substrate treatment unit,
wherein the opening of the door of the second container includes:
opening the door of the second container according to a first opening condition when a treatment fluid used for treating the substrate of the first group and a treatment fluid used for treating the substrate of the second group are the same or homogeneous treatment fluids; and
opening the door of the second container according to a second opening condition when a treatment fluid used for treating the substrate of the first group and a treatment fluid used for treating the substrate of the second group are different treatment fluids, and
a timing of opening the door of the second container is determined based on a treatment progress of the substrate of the first group,
the door of the first container remains open while the substrate of the first group is unloaded from the first container, and
the first opening condition is the time when the last substrate of the substrates of the first group is unloaded from the first container, and
the second opening condition is after the closing of the door of the first container.

19. The method of claim 18, wherein the treatment progress of the substrates of the first group includes the number of substrates of the first group that were not unloaded from the first container, or an opening or closing state of the door of the first container.

20. The method of claim 18, wherein when the substrate unloaded from the first container is treated in the substrate treatment unit and an empty third container is loaded onto a third load port before the door is opened, the door of the second container is opened simultaneously when the door of the second container is opened, and
the third container is a container into which the substrate of the second group, which have been treated in the substrate treatment unit, is loaded.
